(19) United States
(12) Patent Application Publication
(10) Pub. No.: US 2026/0204900 A1
(43) Pub. Date: Jul. 16, 2026

(54) Shunt Circuit

(71) Applicant: Mitsubishi Electric Corporation, Chiyoda-ku, Tokyo (JP)

(72) Inventor: Tomokazu KOJIMA, Chiyoda-ku, Tokyo (JP)

(73) Assignee: Mitsubishi Electric Corporation, Chiyoda-ku, Tokyo (JP)

(21) Appl. No.: 19/133,364

(22) PCT Filed: Dec. 26, 2022
(86) PCT No.: PCT/JP2022/047946

§ 371 Date: May 28, 2025

(51) Int. Cl. H02H 9/04; H03K 17/687

(52) U.S. Cl. CPC H02H 9/045; H03K 17/687

(57) ABSTRACT

A shunt transistor is configured with an N-type field-effect transistor and forms a current path to maintain a voltage of a power supply line at a shunt voltage when a power supply voltage becomes higher than the shunt voltage. A bias circuit and an error amplifier control the shunt transistor such that a state in which the shunt transistor is biased to operate in a subthreshold region and a state in which the shunt transistor is biased to operate in a strong inversion region are formed in order in accordance with a rise of the power supply voltage in a voltage range lower than the shunt voltage. Further, when the power supply voltage becomes higher than the shunt voltage, a gate voltage of the shunt transistor is set to the power supply voltage under a state in which the shunt transistor is operating in the strong inversion region.

### TECHNICAL FIELD

The present disclosure relates to a shunt circuit.

### BACKGROUND ART

The application of energy harvesting that converts natural energy such as sunlight into electricity is expanding. When an energy harvesting power supply is used to generate an input power supply voltage for a circuit such as a system large scale integration (LSI), there is a concern that fluctuations of the generated energy may cause the power supply voltage of the circuit to become excessive and exceed a breakdown voltage of elements in the circuit.

Technology called a shunt circuit is known, which releases power to ground when the input power supply voltage reaches a certain level or higher. Japanese Patent Laying-Open No. 2005-229563 (PTL 1) describes a power supply voltage monitoring circuit having a shunt circuit. In particular, PTL 1 describes a technique to suppress power consumption by the shunt circuit by providing an on/off control signal for the shunt circuit. The shunt circuit is configured to perform switch operation by means of a transistor connected between a power supply line and a ground line to turn on and off according to the on/off control signal.

### CITATION LIST

### Patent Literature

PTL 1: Japanese Patent Laying-Open No. 2005-229563

### SUMMARY OF INVENTION

### Technical Problem

However, in the configuration of PTL 1, the shunt transistor performs switch operation from the off state to the on state to avoid a rise of the power supply voltage in accordance with the logic level of the on/off control signal changed by a comparator when the power supply voltage exceeds a reference voltage.

In this configuration, there is a concern of increased delay time until the shunt transistor goes to a fully on state to ensure a current path necessary for shunting after the rise of the power supply voltage is detected. In particular, in the applications of energy harvesting power supply in which the power supply voltage fluctuations tend to be large as described above, the delay time is not negligible and overvoltage may occur.

The present disclosure is made to solve such a problem and an object of the present disclosure is to provide a shunt circuit configuration that can achieve both an overvoltage preventing effect and lower power consumption.

### Solution to Problem

According to an aspect of the present invention, a shunt circuit includes a voltage detection circuit to detect a power supply voltage, a shunt transistor, and a shunt transistor control circuit to control an operating state of the shunt transistor. The shunt transistor is electrically connected between a power supply line to receive supply of a power supply voltage and a reference voltage line to transmit a reference voltage. The shunt transistor forms a current path for maintaining a voltage of the power supply line at a predetermined shunt voltage when the power supply voltage becomes equal to or higher than the shunt voltage. The shunt transistor is configured with an N-type field-effect transistor. The shunt transistor control circuit controls the shunt transistor such that a first bias state in which the shunt transistor is biased to operate in a subthreshold region and a second bias state in which the shunt transistor is biased to operate in a strong inversion region are formed in order, in accordance with a rise of the power supply voltage detected by the voltage detection circuit in a voltage range lower than the shunt voltage. Further, when the power supply voltage becomes equal to or higher than the shunt voltage, the shunt transistor control circuit sets a gate voltage of the shunt transistor to the power supply voltage under a state in which the shunt transistor is operating in the strong inversion region.

### Advantageous Effects of Invention

According to the present disclosure, the shunt transistor is operated in the subthreshold region by generating a small current in accordance with a rise of the power supply voltage in a region in which the power supply voltage is lower than the shunt voltage, and the shunt transistor is operated in the strong inversion region in accordance with a further rise of the voltage, whereby a current path can be formed by the shunt transistor when the power supply voltage becomes equal to or higher than the shunt voltage. As a result, a shunt circuit that can achieve both an overvoltage preventing effect and lower power consumption can be provided.

### BRIEF DESCRIPTION OF DRAWINGS

FIG. 1 is a block diagram showing a configuration example of a shunt circuit according to a first embodiment.

FIG. 2 is a schematic waveform diagram illustrating the operation of voltage detection circuits shown in FIG. 1.

FIG. 3 is a circuit diagram illustrating a configuration example of a bias circuit shown in FIG. 1.

FIG. 4 is a circuit diagram illustrating a configuration example of an error amplifier shown in FIG. 1.

FIG. 5 is a conceptual diagram showing a current-voltage characteristic of a transistor in a subthreshold region (weak inversion region) and a strong inversion region.

FIG. 6 is a conceptual waveform diagram illustrating the operation of the shunt circuit according to the first embodiment.

FIG. 7 is a conceptual waveform diagram illustrating the operation of a shunt circuit in PTL 1.

FIG. 8 is a conceptual waveform diagram illustrating the operation of the shunt circuit according to the first embodiment.

FIG. 9 is a circuit diagram illustrating a configuration example of a bias circuit according to a second embodiment.

FIG. 10 is a circuit diagram illustrating a configuration example of a start pulse generation circuit shown in FIG. 9.

FIG. 11 is a timing chart illustrating the operation of the bias circuit according to the second embodiment.

### DESCRIPTION OF EMBODIMENTS

Embodiments of the present disclosure will be described in detail below with reference to the drawings. In the following, the same or corresponding parts in the drawings are denoted by the same reference signs and a description thereof is basically not repeated.

### First Embodiment

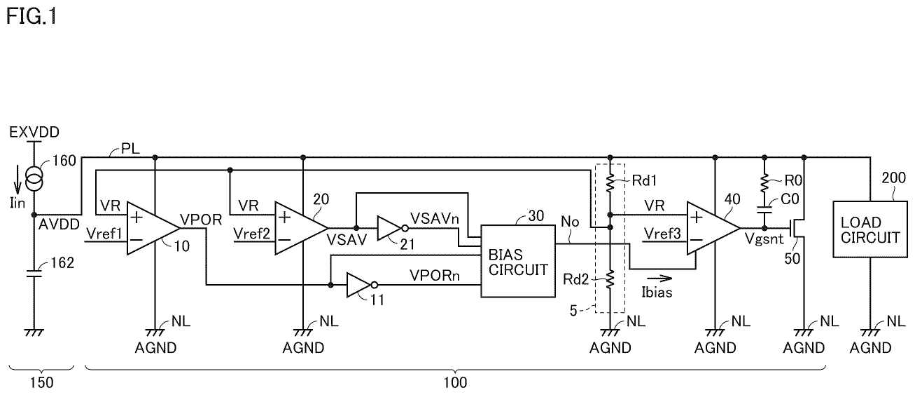

FIG. 1 is a block diagram showing a configuration example of a shunt circuit 100 according to a first embodiment.

As shown in FIG. 1, a power supply line PL receives supply of a power supply voltage AVDD from an input power supply 150. Input power supply 150 has a current source 160 that generates an input current Iin from power generated by energy harvesting or the like (external power supply voltage EXVDD), and a capacitor 162. Capacitor 162 is connected between power supply line PL and a reference voltage line NL that transmits a reference voltage AGND. Current source 160 outputs input current Iin to power supply line PL. Capacitor 162 is charged by input current Iin so that power supply voltage AVDD rises.

Since reference voltage AGND is typically ground (ground voltage), reference voltage AGND is hereinafter referred to as ground voltage AGND, and reference voltage line NL is also referred to as ground line NL. Current source 160 may be configured with an AC current source, and input power supply 150 may include a voltage source.

A load circuit 200 receives power supply voltage AVDD from power supply line PL to operate. Shunt circuit 100 operates such that power supply voltage AVDD on power supply line PL does not exceed a predetermined shunt voltage VRsnt, that is, such that AVDD≤VRsnt is maintained.

Shunt circuit 100 according to the first embodiment includes a voltage divider circuit 5, voltage detection circuits 10 and 20, a bias circuit 30, an error amplifier 40, and a shunt transistor 50.

Voltage divider circuit 5 has resistor elements Rd1 and Rd2 connected in series between power supply line PL and ground line NL. Voltage divider circuit 5 generates a divided voltage VR by dividing power supply voltage AVDD by resistor elements Rd1 and Rd2. When the resistances of resistor elements Rd1 and Rd2 are expressed by the same signs, using the voltage dividing ratio Kv=Rd2/(Rd1+Rd2), VR=Kv·AVDD holds between power supply voltage AVDD and divided voltage VR (0<Kv<1.0).

Voltage detection circuit 10 outputs a detection signal VPOR having a logic level according to a comparison result between power supply voltage AVDD and a predetermined determination voltage VRpor by comparing divided voltage VR and a determination voltage Vref1. Detection signal VPOR corresponds to a so-called power-on reset signal. Determination voltage Vref1 of voltage detection circuit 10 is set to be Kv times determination voltage VRpor, in consideration of the voltage dividing ratio Kv of voltage divider circuit 5 (Vref1=VRpor×Kv).

When power supply voltage AVDD rises from lower than determination voltage VRpor to determination voltage VRpor or higher, voltage detection circuit 10 has an output changing from a logic low level (hereinafter simply referred to as “L level”) to a logic high level (hereinafter simply referred to as “H level”) to generate detection signal VPOR. An inverter 11 generates an inverted signal VPORn of detection signal VPOR.

Voltage detection circuit 20 outputs a detection signal VSAV having a logic level according to a comparison result between power supply voltage AVDD and a predetermined determination voltage VRsav by comparing divided voltage VR and a determination voltage Vref2. Determination voltage VRsav is preset to a voltage higher than determination voltage VRpor and lower than shunt voltage VRsnt (VRpor<VRsav<VRsnt). Determination voltage Vref2 of voltage detection circuit 20 is set to be Kv times determination voltage VRsav, in consideration of the voltage dividing ratio Kv of voltage divider circuit 5 (Vref2=VRsav×Kv). An inverter 21 generates an inverted signal VSAVn of detection signal VSAV.

When power supply voltage AVDD rises from lower than determination voltage VRsav to determination voltage VRsav or higher, voltage detection circuit 20 has an output changing from L level to H level to generate detection signal VSAV.

As a result, by generating detection signals VPOR and VSAV, voltage detection circuits 10 and 20 can detect which one of the following power supply voltage AVDD lower than shunt voltage VRsnt belongs to: (i) the voltage range of AGND≤AVDD<VRpor corresponding to “third voltage range” (VPOR=VSAV=L level); (ii) the voltage range of VRpor≤AVDD<VRsav corresponding to “second voltage range” (VPOR=H level, VSAV=L level); and (iii) the voltage range of VRsav≤AVDD<VRsnt corresponding to “first voltage range” (VPOR=VSAV=H level).

Shunt transistor 50 is configured with an N-type field-effect transistor and is connected between power supply line PL and ground line NL. The gate of shunt transistor 50 is connected to the output node of error amplifier 40.

Error amplifier 40 outputs an amplified voltage of a voltage difference between power supply voltage AVDD and predetermined shunt voltage VRsnt to the gate of shunt transistor 50 by comparing divided voltage VR with a determination voltage Vref3. Determination voltage Vref3 of error amplifier 40 is set to be Kv times shunt voltage VRsnt, in consideration of the voltage dividing ratio Kv of voltage divider circuit 5 (Vref3=VRsnt×Kv). Bias circuit 30 receives detection signals VPOR and VSAV and inverted signals VPORn and VSAVn, and supplies a bias current Ibias equivalent to an operating current of a transistor group (described later) included in error amplifier 40. Bias current Ibias is controlled in accordance with detection signals VPOR and VSAV.

Generally, a resistor element R0 and a capacitor CO that constitute an RC circuit for phase compensation are connected in series between the gate of shunt transistor 50 and power supply line PL. As a result, when the output voltage of error amplifier 40 changes, a gate voltage Vgsnt of shunt transistor 50 changes with a time delay that follows a time constant of the RC circuit for phase compensation.

When power supply voltage AVDD becomes equal to or higher than shunt voltage VRsnt (AVDD≥VRsgt), gate voltage Vgsnt is set to H level, that is, power supply voltage AVDD, by error amplifier 40. On the other hand, in a region in which power supply voltage AVDD is lower than shunt voltage VRsnt (AVDD<VRsgt), gate voltage Vgsnt changes in accordance with an operating state (bias state) of the transistor group (described later) included in error amplifier 40 and shunt transistor 50, which is determined depending on bias current Ibias output from bias circuit 30, as will be described later.

In this way, the operating state of shunt transistor 50 changes in accordance with the operation of bias circuit 30 and error amplifier 40. In other words, bias circuit 30 and error amplifier 40 can constitute an embodiment of a “shunt transistor control circuit”.

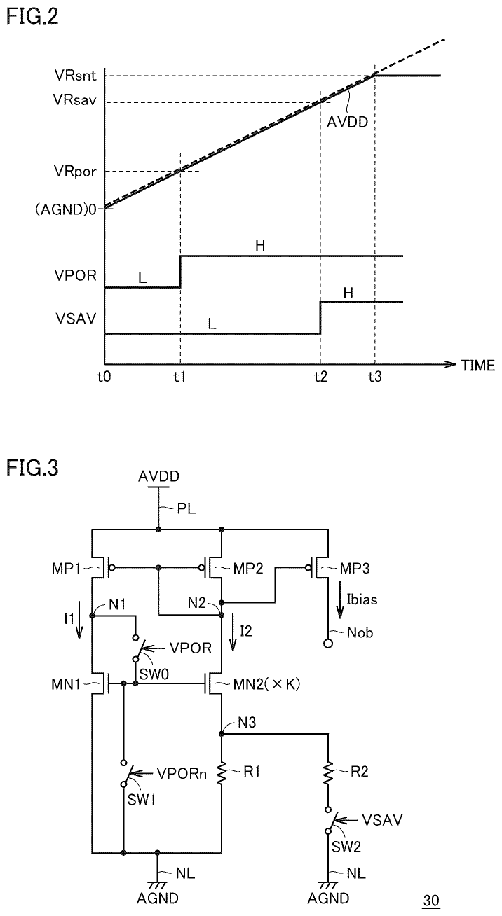

FIG. 2 is a schematic waveform diagram illustrating the operation of voltage detection circuits 10 and 20 shown in FIG. 1. FIG. 2 shows an example of the operation when power supply voltage AVDD rises upon startup of input power supply 150 (for example, the start of power generation by energy harvesting).

As shown in FIG. 2, when input power supply 150 is started at time t0, power supply voltage AVDD rises and becomes equal to or higher than determination voltage VRpor at time t1, and then becomes equal to or higher than determination voltage VRsav at time t2.

As a result, detection signal VPOR from voltage detection circuit 10 is at L level from time t0 to t1 and at H level after time t1. Similarly, detection signal VSAV from voltage detection circuit 20 is at L level from time t0 to t2 and at H level after time t2.

After time t2, power supply voltage AVDD rises with both detection signals VPOR and VSAV generated (VPOR=VSAV=H level). At time t3, when power supply voltage AVDD reaches shunt voltage VRsnt, shunt transistor 50 goes to a fully on state and a current path is formed between power supply line PL and ground line NL to prevent power supply voltage AVDD from rising.

In FIG. 2, a waveform of power supply voltage AVDD in a case where shunt circuit 100 is not arranged is illustrated by a dotted line for comparison. As a result of the arrangement of shunt circuit 100, after time t3, power supply voltage AVDD is maintained at shunt voltage VRsnt.

As an example, in the present embodiment, shunt voltage VRsnt=5 [V], whereas determination voltage VRpor is about 1.5 [V] and determination voltage VRsav is about 4 [V]. In the present embodiment, it is assumed that a threshold voltage Vt (design value) of each transistor, including shunt transistor 50, is 1.0 [V].

A configuration example and detailed operation of bias circuit 30 and error amplifier 40 will now be described.

FIG. 3 is a circuit diagram illustrating a configuration example of bias circuit 30 shown in FIG. 1.

As shown in FIG. 3, bias circuit 30 includes transistors MN1 and MN2, each configured with an N-type field-effect transistor, transistors MP1 to MP3, each configured with a P-type field-effect transistor, resistor elements R1 and R2, and switches SW0 to SW2.

Transistors MP1 and MP2 are connected between power supply line PL and nodes N1 and N2, respectively. Transistor MP3 is connected between power supply line PL and an output node Nob of bias current Ibias. Since the gates of transistors MP1 to MP3 are connected to node N2, transistor MP2 is diode connected and transistors MP1 to MP3 constitute a current mirror.

Here, a description will be given assuming that each of transistors MP1 to MP3 has an equivalent transistor size. Therefore, I1=I2=Ibias holds between current I1 at node N1, current I2 at node N2, and bias current Ibias.

Transistor MN1 is connected between node N1 and ground line NL, and transistor MN2 is connected between nodes N2 and N3. Transistor MN2 has a transistor size of K times (K is a real number of K>2) that of transistor MN1.

The gates of transistors MN1 and MN2 are connected to node N1 through switch SW0 and connected to ground line NL through switch SW1. Switch SW0 turns off when detection signal VPOR is at L level, and turns on when detection signal VPOR is at H level. Conversely, switch SW1 turns off when detection signal VPOR is at H level, and turns on when detection signal VPOR is at L level, in accordance with inverted signal VPORn of detection signal VPOR. Therefore, the gates of transistors MN1 and MN2 are connected to node N1 or ground line NL (ground voltage AGND) in accordance with detection signal VPOR.

Resistor element R1 is connected between node N3 and ground line NL. Resistor element R2 is connected between node N3 and ground line NL in series with switch SW2. Hereinafter, the electrical resistances of resistor elements R1 and R2 are also expressed by R1 and R2. Switch SW2 turns on when detection signal VSAV is at H level, and turns off when detection signal VSAV is at L level.

When both detection signals VPOR and VSAV are at L level (AGND≤AVDD<VRpor: third voltage range), switches SW0 and SW2 turn off and switch SW1 turns on in bias circuit 30. Therefore, in bias circuit 30, the gate voltages of transistors MN1 and MN2 become ground voltage AGND and the gate-source voltage Vgs becomes zero, so that transistors MN1 and MN2 go to a fully off state. As a result, current I1=I2=0, and bias current Ibias also becomes zero (Ibias=0).

The operation of bias circuit 30 when detection signal VPOR is at H level and detection signal VSAV is at L level (VPOR≤AVDD<VRsav: second voltage range) will now be described. In this case, switches SW1 and SW2 turn off and switch SW0 turns on. As a result, the gates of transistors MN1 and MN2 are disconnected from ground line NL and connected to node N1, so that in bias circuit 30, current I2 corresponding to the electrical resistance (R1) of resistor element R1 is generated, and I2=I1=Ibias because of the current mirror with transistors MP1 to MP3. Here, resistor element R1 is designed to have an electrical resistance (R1), for example, about several hundred [MΩ], such that a drain current Ids on the order of nanoampere (nA) (for example, the order of 10 [nA]) for currents I1, I2, and Ibias in this case to allow the field-effect transistors to operate in the subthreshold region (weak inversion region) is generated.

Here, drain current Ids in the subthreshold region of the field-effect transistors is represented by equation (1) below, using gate-source voltage Vgs, threshold voltage Vt, Boltzmann's constant k, temperature T[K], and thermal voltage VT expressed by elementary charge. Coefficients η and I0 in equation (1) are constants determined by the process.

$$Ids = I 0 \cdot ( W / L ) \cdot exp ( ( V gs - V t ) / ( η \cdot V T ) ) where V T = k \cdot T / q \qquad ( 1 )$$

Solving I1=I2 for transistors MN1 and MN2 operating in the subthreshold region yields equation (2) below.

$$I 1 = I 2 = η \cdot V T \cdot ln ( K ) / R 1 \qquad ( 2 )$$

In other words, by adjusting the electrical resistance of resistor element R1, bias circuit 30 can generate bias current Ibias=Ib1 equivalent to drain current Ids when each field-effect transistor operates in the subthreshold region. As described above, Ib1 is adjusted to the order of 10 (nA).

The operation of bias circuit 30 when both detection signals VPOR and VSAV are at H level (VRsav≤AVDD<VRsnt: first voltage range) will now be described. In this case, switch SW1 turns off and switches SW0 and SW2 turn on. As a result, compared with when detection signal VPOR=H level and detection signal VSAV=L level, bias circuit 30 has the electrical resistance between node N3 and ground line NL changing as resistor elements R1 and R2 are connected in parallel between node N3 and ground line NL.

Here, resistor element R2 is designed to have an electrical resistance (R2), for example, about 100 [kΩ], such that drain current Ids on the order of microampere (μA) (for example, the order of 10 [μA]) for currents I1, 12, and Ibias in this case to allow the field-effect transistors to operate in the strong inversion region is generated. In this way, since R2<<R1, the electrical resistance between node N3 and ground line NL can be approximated to R2 when switch SW2 is on.

Here, drain current Ids in the strong inversion region of the field-effect transistors is represented by equations (3) and (4) below, using gate-source voltage Vgs, threshold voltage Vt, and coefficient β. In equation (4), u is the electron mobility, Cox is the gate capacitance per unit area, W is the gate width, and L is the gate length.

$$Ids = ( 1 / 2 ) \cdot β \cdot {( V gs - V t )}^{2} \qquad ( 3 )$$

$$β = μ \cdot Cox / ( W / L ) \qquad ( 4 )$$

Solving I1=I2 for transistors MN1 and MN2 operating in the strong inversion region yields equation (5) below.

$$I 1 = I 2 = ( 2 / β ) \cdot ( 1 / R {2}^{2} ) \cdot ( 1 - 1 ) \qquad ( 5 )$$

By adjusting the electrical resistance of resistor element R2, bias circuit 30 can generate bias current Ibias=Ib2 equivalent to drain current Ids when each field-effect transistor operates in the strong inversion region. As described above, Ib2 is adjusted to the order of 10 (μA).

In this way, bias circuit 30 controls bias current Ibias such that Ibias=0 (VPOR=VSAV=L level), Ibias=Ib1 (VPOR=H level, VSAV=L level), or Ibias=Ib2 (VPOR==VSAV=H level), in accordance with detection signals VPOR and VSAV.

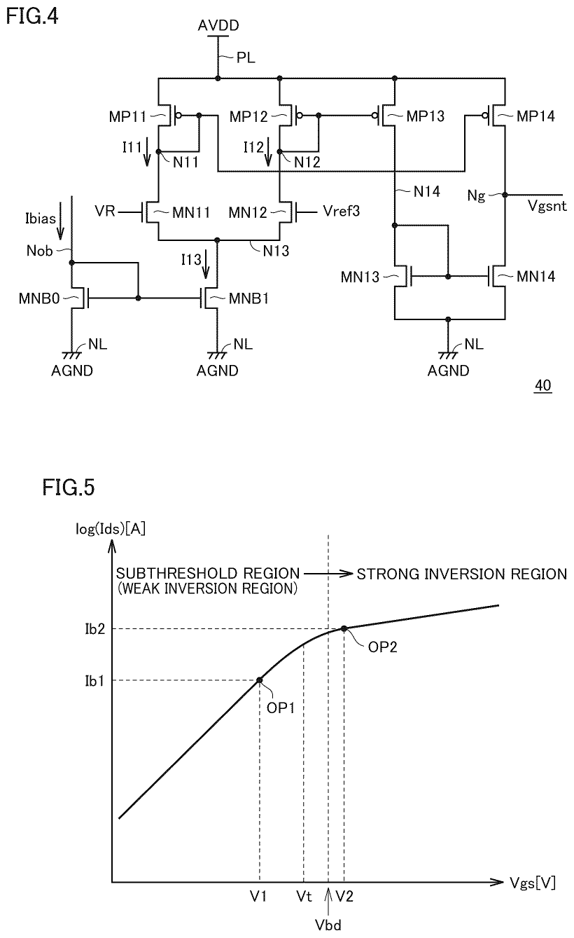

FIG. 4 is a circuit diagram illustrating a configuration example of error amplifier 40 shown in FIG. 1.

As shown in FIG. 4, error amplifier 40 includes MNB0, MNB1, MN11 to MN14, each configured with an N-type field-effect transistor, and transistors MP11 to MP14, each configured with a P-type field-effect transistor.

Transistors MP11 and MP12 are connected between power supply line PL and nodes N11 and N12, respectively. The gates of transistors MP11 and MP12 are connected to nodes N11 and N12, respectively, and transistors MP11 and MP12 are diode connected.

Further, transistor MP13 is connected between power supply line PL and node N14, and transistor MP14 is connected between power supply line PL and an output node Ng connected to the gate of shunt transistor 50. The gate of transistor MP13 is connected to the gate of transistor MP12, and the gate of transistor MP14 is connected to the gate of transistor MP11. Transistors MP11 to MP14 constitute a folded active load.

Transistor MN13 is connected between node N14 and ground line NL, and transistor MN14 is connected between output node Ng and ground line NL. The gates of transistors MN13 and MN14 are connected to node N14, and transistor MN13 is diode connected. Transistors MN13 and MN14 constitute an active load. Transistor MN14 is connected between the gate of shunt transistor 50 and ground line NL. Error amplifier 40 including transistors MN13 and MN14 and shunt transistor 50 as a whole constitute a so-called shunt amplifier (shunt regulator).

Transistor MN11 is connected between nodes N11 and N13, and transistor MN12 is connected between nodes N12 and N13. Divided voltage VR is input to the gate of transistor MN11, and determination voltage Vref3 (Vref3=Kv·VRsnt) corresponding to shunt voltage VRsnt is input to the gate of transistor MN12. Transistors MN11 and MN12 constitute a differential amplification unit.

Transistor MNB1 is connected between node N13 and ground line NL, and transistor MNB0 is connected between output node Nob of bias circuit 30 and ground line NL. The gates of transistors MNB0 and MNB1 are connected to output node Nob. Therefore, transistors MNB0 and MNB1 constitute a current mirror to allow current I13 flowing through node N13 to become bias current Ibias from bias circuit 30. As a result, the operating current flowing through the transistor group included in error amplifier 40 is controlled to bias current Ibias from bias circuit 30.

In the region of VR>Vref3 (i.e., AVDD≥VRsnt), the output from error amplifier 40 changes to H level, and gate voltage Vgsnt changes to power supply voltage AVDD, so that shunt transistor 50 turns fully on. In contrast, in the region of VR<Vref3 (i.e., AVDD<VRsnt), gate voltage Vgsnt from shunt transistor 50 changes depending on the operating current (Ibias).

FIG. 5 is a conceptual diagram showing a current-voltage characteristic of a field-effect transistor in the subthreshold region (weak inversion region) and the strong inversion. The horizontal axis in FIG. 5 shows gate-source voltage Vgs, and the vertical axis shows drain current Ids on a logarithmic scale.

As shown in FIG. 5, in the subthreshold region (weak inversion region), drain current Ids changes according to an exponential function with respect to gate-source voltage Vgs, as represented by equation (1) above. On the other hand, in the strong inversion region, drain current Ids increases with the square of gate-source voltage Vgs, as represented by equation (3) above.

Gate-source voltage Vgs=Vbd, which is the boundary between the subthreshold region (weak inversion region) and the strong inversion region, relative to threshold voltage Vt of the transistor is represented by equation (6) below.

$$V bd = V t + 2 \cdot η \cdot V T \qquad ( 6 )$$

As explained with reference to FIG. 4, when Vref1≤VR<Vref2 (i.e., VRpor≤AVDD<VRsav), bias current Ibias is controlled to Ib1 by bias circuit 30. In this voltage range, since VR<Vref3 (AVDD<VRpsht), shunt transistor 50 is not turned on, and each transistor of the transistor group included in error amplifier 40 and shunt transistor 50 is in a bias state at an operating point OP1 in the subthreshold region as bias current Ibias=Ib1 flows. This bias state corresponds to the “first bias state”.

The gate voltage of each transistor in this case is determined to be a voltage value V1, as gate-source voltage Vgs in the subthreshold region, in accordance with the operating point OP1 on the Vgs-Ids characteristic line in the subthreshold region in FIG. 5.

For example, bias current Ibias=Ib1 when VPOR=H level and VSAV=L level (i.e., VRpor≤AVDD<VRsav) can be adjusted by the electrical resistance of resistor element R1 so that V1 is about Vt−0.2 [V] relative to threshold voltage Vt.

Next, in the voltage range of Vref2≤VR<Vref3 (i.e., VRsav≤AVDD<VRsnt), bias current Ibias is controlled to Ib2 by bias circuit 30. Even in this voltage range, shunt transistor 50 is not turned on, and each transistor of the transistor group included in error amplifier 40 and shunt transistor 50 is in a bias state of operating within the strong inversion region as bias current Ibias=Ib2 flows. This bias state corresponds to the “second bias state”.

When detection signal VSAV changes from L level to H level and bias current Ibias changes to Ib2, gate voltage Vgsnt is determined to be a voltage value V2, as gate-source voltage Vgs in the strong inversion region, in accordance with an operating point OP2 on the Vgs-Ids characteristic line in the subthreshold region in FIG. 5.

For example, bias current Ibias=Ib2 when detection signal VPOR=VSAV=H level (i.e., in the range of VRsav≤AVDD<VRsnt) can be adjusted to such an extent that V2=Vt+0.2 [V] relative to threshold voltage Vt by adjusting the electrical resistance value of resistor element R2.

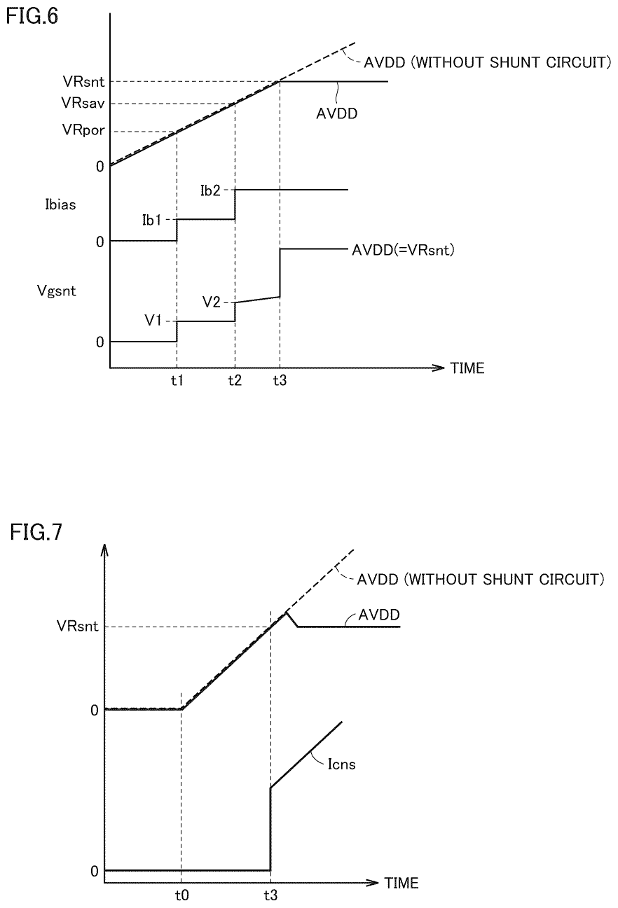

As a result, shunt circuit 100 according to the first embodiment can operate as shown in FIG. 6 for a rise of power supply voltage AVDD.

Referring to FIG. 6, in the voltage range in which power supply voltage AVDD at time t0 to t1 is lower than determination voltage VRpor (i.e., VPOR=VSAV=L level), bias circuit 30 controls bias current Ibias to zero, so that the transistor group included in error amplifier 40 is in a fully off state. As a result, gate voltage Vgsnt of shunt transistor 50 is controlled to zero, and shunt transistor 50 also goes to a fully off state. The leakage current of each transistor and shunt transistor 50 shown in FIG. 3 and FIG. 4 in this state is on the order of pA (picoampere).

Next, in the voltage range of VRpor≤AVDD<VRsav (i.e., VPOR=H level, VSAV=L level) at time t1 to t2 when power supply voltage AVDD rises, bias circuit 30 controls bias current Ibias to Ibias=Ib1 (FIG. 5) such that each transistor of error amplifier 40 and shunt transistor 50 operates at the operating point OP1 (FIG. 5) in the subthreshold region in which gate-source voltage Vgs is near threshold voltage Vt. As a result, gate voltage Vgsnt of shunt transistor 50 is controlled to Vb1, and shunt transistor 50 goes to a bias state in the subthreshold region (weak inversion region). The leakage current of each transistor and shunt transistor 50 shown in FIG. 3 and FIG. 4 in this state is on the order of nA (nanoampere).

In the voltage range of VRsav≤AVDD<VRsnt (i.e., VPOR=VSAV=H level) at time t2 to t3 when power supply voltage AVDD further rises, bias circuit 30 controls bias current Ibias such that each transistor of error amplifier 40 and shunt transistor 50 operates in the strong inversion region.

At time t2 when power supply voltage AVDD reaches determination voltage VRsav, bias circuit 30 controls bias current Ibias to Ibias=Ib2 (FIG. 5) such that each transistor of error amplifier 40 and shunt transistor 50 operates at the operating point OP2 (FIG. 5) in the strong inversion region in which gate-source voltage Vgs is near threshold voltage Vt. As a result, gate voltage Vgsnt of shunt transistor 50 is controlled to Vb2, and shunt transistor 50 goes to a bias state in the strong inversion region. The leakage current of each transistor and shunt transistor 50 shown in FIG. 3 and FIG. 4 in this state is on the order of uA (microampere).

Between time t2 to t3, if power supply voltage AVDD rises above determination voltage VRsav after time t2, the current of transistor MP1 slightly increases, and as a result, the current of transistor MN14 also slightly increases, resulting in a slight increase of gate voltage Vgsnt. In this voltage range, gate voltage Vgsnt is at least lower than shunt voltage VRsnt.

After time t3 when power supply voltage AVDD further rises and falls within the voltage range of AVDD>VRsnt, the output of error amplifier 40 changes to H level, so that gate voltage Vgsnt rises to power supply voltage AVDD and shunt transistor 50 goes to a fully on state. As a result, a current path (shunt path) from power supply line PL to ground line NL is formed, so that even if power supplied from input power supply 150 increases, power supply voltage AVDD does not rise as shown by a dotted line, and power supply voltage AVDD is maintained at shunt voltage VRsnt.

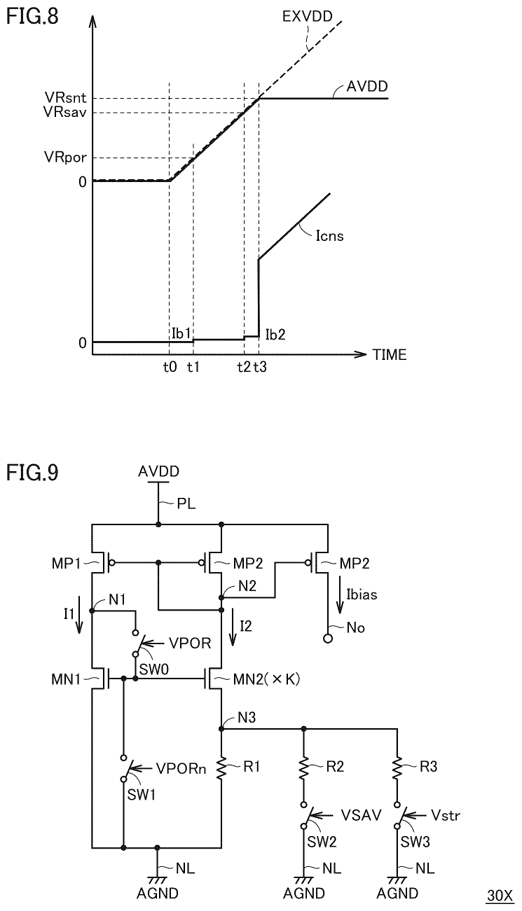

Referring now to FIG. 7 and FIG. 8, the operation is compared between the shunt circuit in PTL 1 and the shunt circuit according to the first embodiment. In FIG. 7 and FIG. 8, the waveform of power supply voltage AVDD in a case where the shunt circuit is not arranged is shown by a dotted line, and the conceptual waveforms of power supply voltage AVDD and consumption current Icns when the shunt circuit is arranged are shown, in the same manner as in FIG. 2.

FIG. 7 shows the operation of the shunt circuit in PTL 1.

Referring to FIG. 7, for power supply voltage AVDD started at time t0 and rising, in the shunt circuit described in PTL 1, in a period until power supply voltage AVDD rises to shunt voltage VRsnt (time t0 to t3), each transistor included in the shunt circuit can be made equivalent to the “full off state (leakage current on the order of pA)” in the present embodiment by the on/off control signal of the shunt circuit. Therefore, consumption current Ions in this period can be almost zero (pA order).

However, at time t3 when power supply voltage AVDD reaches shunt voltage VRsnt, the shunt transistor needs to switch from the fully off state to the strong inversion region and then to the fully on state. Therefore, the gate voltage needs to change from the 0 [V] state to the strong inversion region, that is, the operating point OP2 in FIG. 6. As described above, assuming that Vt=1.0 [V] and the voltage value V2 at the operating point OP2 is Vt+0.2 [V], the turning-on of the shunt transistor requires a gate charge time to increase the gate voltage from 0 [V] to 1.2 [V].

For example, assuming that the sum of the gate capacitance of the shunt transistor and the capacitance of capacitor CO for phase compensation shown in FIG. 1 is 10 [pF] and that the gate charge current (equivalent to the operating current of the error amplifier) is 10 [μA], the gate charge time Tc necessary for the shunt transistor 50 to operate in the strong inversion region is 10 [pF]0.1.2 [V]/10 [μA]=1.2 [us].

Therefore, when the rate of change of power supply voltage AVDD is high relative to the gate charge time, there is a delay in the turning-on of shunt transistor 50 for the rise of power supply voltage AVDD, as shown in FIG. 7. This may cause power supply voltage AVDD to rise above shunt voltage VRsnt, resulting in an overvoltage period.

In contrast, FIG. 8 shows the operation of shunt circuit 100 according to the first embodiment.

In FIG. 8, for a change of power supply voltage AVDD equivalent to that of FIG. 7, each transistor included in bias circuit 30 and error amplifier 40 and shunt transistor 50 change from a fully off state to a bias state in the subthreshold region (at time t1) and further change to a bias state in the strong inversion region (time t2), in accordance with a rise of power supply voltage AVDD, before time t3 when AVDD≥VRsnt.

In other words, after power supply voltage AVDD becomes equal to or higher than determination voltage VRsav, power supply voltage AVDD reaches shunt voltage VRsnt while shunt transistor 50 is biased in the strong inversion region, so that the shunt path can be formed by shunt transistor 50 quickly at the timing when AVDD≥VRsnt.

Assuming that the voltage value V1 at the operating point OP1 in the bias state in the subthreshold region (weak inversion region) is Vt−0.2 [V] as described above, the amount of rise of the gate voltage required to change shunt transistor 50 from the bias state in the weak inversion region to the bias state in the strong inversion region is 0.4 [V]. Therefore, under the same capacitance value of 10 [pF] and charge current of 10 [μs] as described with reference to FIG. 7, the gate charge time Tc for shunt transistor 50 to operate in the strong inversion region is 10 [pF]0.0.4 [V]/10 [μA]=0.4 [μs], which is much shorter than in the example in FIG. 7.

As a result, it is possible to suppress the overvoltage caused by the delay in formation of the shunt path by shunt transistor 50 for a rise of power supply voltage AVDD.

In shunt circuit 100 according to the first embodiment, consumption current Icns is almost zero (leakage current on the order of pA) in the period from time t0 to t3 in FIG. 8, a current on the order of nA (Ib1 in FIG. 6) is consumed in the period from time t1 to t2, and a current on the order of μA (Ib2 in FIG. 6) is consumed in the period from time t2 to t3, but these currents are small and have smaller drawbacks compared with the effect of suppressing overvoltage described above. In particular, a preliminary period of operating in the subthreshold region with a small current is provided before operating in the strong inversion region, thereby achieving both lower power consumption and high-speed operation.

Therefore, the shunt circuit according to the first embodiment allows shunt transistor 50 to operate in the subthreshold region and the strong inversion region in advance with consumption of a small current (on the order of nA and uA) in response to a rise of power supply voltage AVDD, before power supply voltage AVDD rises to shunt voltage VRsnt. As a result, a current path (shunt path) can be quickly formed by shunt transistor 50 when power supply voltage AVDD reaches shunt voltage VRsnt, thereby enhancing the effect of suppressing overvoltage without significantly increasing power consumption.

### Second Embodiment

In a second embodiment, an improved circuit configuration for further accelerating the formation of a current path by shunt transistor 50 when power supply voltage AVDD reaches shunt voltage VRsnt will be described.

FIG. 9 is a circuit diagram illustrating a configuration example of a bias circuit 30X according to the second embodiment.

The shunt circuit according to the second embodiment is configured such that bias current Ibias is generated by bias circuit 30X in FIG. 9 instead of bias circuit 30 (FIG. 3) in shunt circuit 100 described in the first embodiment. In other respects, the second embodiment is similar to the first embodiment and a detailed description thereof will not be repeated.

Referring to FIG. 9, bias circuit 30X according to the second embodiment differs from bias circuit 30 shown in FIG. 3 in that it further includes a resistor element R3 and a switch SW3 connected in series between node N3 and ground line NL. Resistor element R3 and switch SW3 are connected in parallel with resistor element R2 and switch SW2. The other configuration of bias circuit 30X is the same as bias circuit 30.

Switch SW3 is turned on and off in accordance with a start pulse Vstr. Specifically, switch SW3 is turned off in a L level period of start pulse Vstr, and switch SW3 is turned on in a H level period of start pulse Vstr.

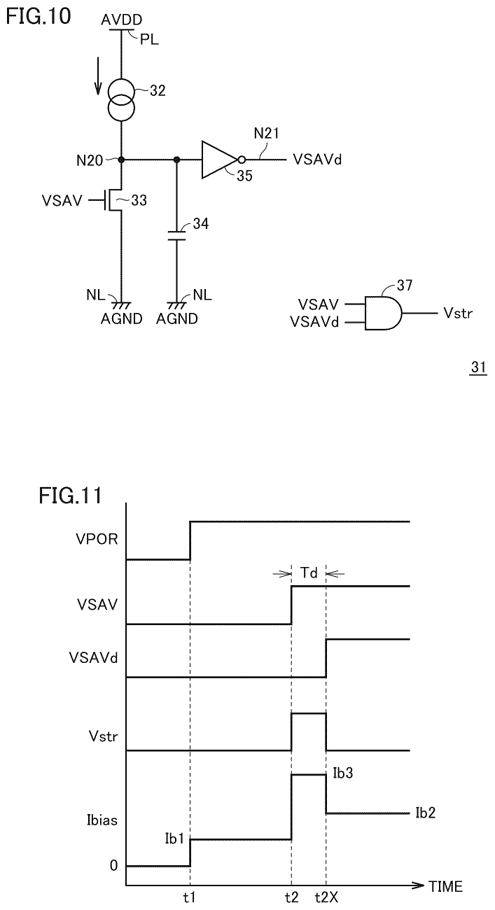

FIG. 10 is a circuit diagram illustrating a configuration example of a circuit for generating start pulse Vstr.

Referring to FIG. 10, a start pulse generation circuit 31 has a current source 32, a transistor 33, a capacitor 34, an inverter 35, and a logic gate 37.

Current source 32 is connected between power supply line PL and node N20. For example, current source 32 can be configured with a diode-connected transistor. Transistor 33 is configured with, for example, an N-type field-effect transistor and is connected between node N20 and ground line NL. Detection signal VSAV from voltage detection circuit 20 is input to the gate of transistor 33.

Capacitor 34 is connected between node N20 and ground line NL. Inverter 35 outputs a voltage signal to node N21 by inverting the voltage level of node N20.

In a L level period of detection signal VSAV, transistor 33 is turned off, and capacitor 34 is charged by a current from current source 32, so that the voltage at node N20 is power supply voltage AVDD, that is, H level. In this state, inverter 35 outputs a voltage signal at L level to node N21.

When detection signal VSAV changes from L level to H level, transistor 33 turns on to cause capacitor 34 to be discharged, so that the voltage at node N20 changes to ground voltage AGND, that is, L level. As a result, the operation of inverter 35 also changes the voltage at node N21 from L level to H level.

However, from the timing when detection signal VSAV changes from L level to H level to the timing when the voltage at node N21 changes from L to H level, there is a delay time until the voltage at node N20 changes from H to L level due to the discharge of capacitor 34. This delay time depends on the product of the output current of current source 32 and the capacitance of capacitor 34.

In this way, inverter 35 inverts the voltage level of node N20 and outputs the inverted output to generate a delay signal VSAVd of detection signal VSAV, which is in phase with detection signal VSAV and to which the delay signal is added, at node N21.

Logic gate 37 generates start pulse Vstr in accordance with the result of logical AND operation of detection signal VSAV from voltage detection circuit 20 and delay signal VSAVd generated at node N21.

FIG. 11 is a timing chart illustrating the operation of the bias circuit according to the second embodiment.

As shown in FIG. 11, at time t1, detection signal VPOR from voltage detection circuit 10 changes from L level to H level, and at time t2, detection signal VSAV from voltage detection circuit 20 changes from L level to H level, in the same manner as in FIG. 2.

Delay signal VSAVd lags behind detection signal VSAV by delay time Td and changes from L level to H level at time t2X. Therefore, start pulse Vstr, which is obtained by logical AND of detection signal VSAV and its delay signal VSAVd, is a pulse signal set to H level in a period from time t2 to t2X and set to L level in the other period. As understood from FIG. 11, in a H level period of start pulse Vstr, detection signals VPOR and VSAV are also at H level.

Therefore, in FIG. 9, in a H level period of start pulse Vstr, switch SW1 is turned off and switches SW0, SW2, and SW3 are turned on. As a result, resistor elements R1 to R³ are connected in parallel between node N3 and ground line NL. Here, the electrical resistance of resistor element R3 is designed to be lower than the electrical resistance of resistor element R2. For example, the electrical resistance of resistor element R2 is about 100 [kΩ], whereas the electrical resistance of resistor element R3 is designed to be about 10 [kΩ]. In this way, the bias current Ibias=Ib2 when resistor elements R1 and R2 are connected in parallel is on the order of 10 [μA], whereas the bias current Ibias=Ib3 when resistor elements R1 to R3 are connected in parallel can be on the order of 100 [μA] (Ib3>Ib2).

As a result, as shown in FIG. 11, bias current Ibias is set to Ib3 (for example, 100 [μA]), which is larger than Ib2 (for example, the order of 10 [μA]) in a certain period (time t2 to t2X) immediately after detection signal VSAV changes to H level. The length of the H level period of start pulse Vstr, which is equivalent to delay time Td applied by start pulse generation circuit 31, can be adjusted by the output current of current source 32 and/or the capacitance of capacitor 34 as described above.

As a result, bias current Ibias, that is, the operating current of error amplifier 40, can be increased in a certain period immediately after shunt transistor 50 starts operating in the strong inversion region, thereby increasing the rate of change of gate voltage Vgsnt when power supply voltage AVDD reaches shunt voltage VRsnt.

As a result, a current path (shunt path) can be formed more quickly by shunt transistor 50 when power supply voltage AVDD reaches shunt voltage VRsnt, thereby enhancing the effect of suppressing overvoltage.

Embodiments disclosed here should be understood as being illustrative rather than being limitative in all respects. The scope of the present disclosure is shown not by the foregoing description but by the claims and is intended to include all changes within the meaning and scope of the claims and equivalents.

### REFERENCE SIGNS LIST

5 voltage divider circuit, 10, 20 voltage detection circuit, 30, 30X bias circuit, 31 start pulse generation circuit, 32, 160 current source, 33, MN1, MN2, MN11 to MN14, MNB0, MNB1, MP1 to MP3, MP11 to MP14 transistor, 34, 162, CO capacitor, 35 inverter, 37 logic gate, 40 error amplifier, 50 shunt transistor, 100 shunt circuit, 150 input power supply, 200 load circuit, AGND ground voltage (reference voltage), AVDD power supply voltage, EXVDD external power supply voltage, Ibias bias current, Icns consumption current, NL ground line (reference voltage line), OP1, OP2 operating point, PL power supply line, R0 to R3, Rd1, Rd2 resistor element, SW0 to SW3 switch, Td delay time, VPOR, VSAV detection signal, VPORn inverted signal (detection signal), VR divided voltage, VRpor, VRsav, Vref1 to Vref3 determination voltage, VRsnt shunt voltage, VSAVd delay signal (detection signal), Vgsnt gate voltage (shunt transistor), Vstr start pulse, Vt threshold voltage.

1. A shunt circuit comprising:
a shunt transistor electrically connected between a power supply line to receive supply of a power supply voltage and a reference voltage line to transmit a reference voltage, the shunt transistor forming a current path for maintaining a voltage of the power supply line at a predetermined shunt voltage when the power supply voltage becomes equal to or higher than the shunt voltage;
a voltage detection circuit to detect the power supply voltage; and
a shunt transistor control circuit to control an operating state of the shunt transistor, wherein
the shunt transistor is configured with an N-type field-effect transistor,
the shunt transistor control circuit controls the shunt transistor such that a first bias state in which the shunt transistor is biased to operate in a subthreshold region and a second bias state in which the shunt transistor is biased to operate in a strong inversion region are formed in order, in accordance with a rise of the power supply voltage detected by the voltage detection circuit, in a voltage range lower than the shunt voltage, and
when the power supply voltage becomes equal to or higher than the shunt voltage, the shunt transistor control circuit sets a gate voltage of the shunt transistor to the power supply voltage under a state in which the shunt transistor is operating in the strong inversion region.

2. The shunt circuit according to claim 1, wherein
the shunt transistor control circuit includes
an error amplifier to set the gate voltage by amplifying a voltage difference between the power supply voltage and the shunt voltage, and
a bias circuit to supply an operating current flowing through a field-effect transistor group included in the error amplifier,
the field-effect transistor group includes an N-type field-effect transistor electrically connected between a gate of the shunt transistor and the reference voltage line,
the bias circuit supplies the operating current with a first current for allowing the field-effect transistor group to operate in the subthreshold region, in the first bias state, and supplies the operating current with a second current for allowing the field-effect transistor group to operate in the strong inversion region, in the second bias state, and
when the power supply voltage is lower than the shunt voltage, the gate voltage is determined by the shunt transistor going to a bias state in accordance with the operating current, and when the power supply voltage is equal to or higher than the shunt voltage, the gate voltage is set to the power supply voltage by the error amplifier.

3. The shunt circuit according to claim 1, wherein
the voltage detection circuit is configured to detect a voltage range to which the power supply voltage belongs, among a first voltage range, a second voltage range on a lower voltage side than the first voltage range, and a third voltage range on a lower voltage side than the second voltage range, wherein a voltage range lower than the shunt voltage is divided into the first, second, and third voltage ranges,
the shunt transistor control circuit controls an operating state of the shunt transistor in accordance with a voltage range to which the power supply voltage belongs and a result of comparison between the power supply voltage and the shunt voltage,
the shunt transistor control circuit sets the gate voltage to the reference voltage when the power supply voltage belongs to the third voltage range, biases the shunt transistor to operate in the subthreshold region when the power supply voltage belongs to the second voltage range, biases the shunt transistor to operate in the strong inversion region when the power supply voltage belongs to the first voltage range, and sets the gate voltage to the power supply voltage when the power supply voltage becomes equal to or higher than the shunt voltage.

4. The shunt circuit according to claim 3, wherein
the shunt transistor control circuit includes
an error amplifier to set the gate voltage by amplifying a voltage difference between the power supply voltage and the shunt voltage, and
a bias circuit to supply an operating current flowing through a field-effect transistor group included in the error amplifier,
the field-effect transistor group includes an N-type field-effect transistor electrically connected between a gate of the shunt transistor and the reference voltage line,
the bias circuit sets the operating current to zero when the power supply voltage belongs to the third voltage range, supplies the operating current with a first current for allowing the field-effect transistor group to operate in the subthreshold region when the power supply voltage belongs to the second voltage range, and supplies the operating current with a second current for allowing the field-effect transistor group to operate in the strong inversion region when the power supply voltage belongs to the first voltage range, and
when the power supply voltage is lower than the shunt voltage, the gate voltage is determined by the shunt transistor going to a bias state in accordance with the operating current, and when the power supply voltage is equal to or higher than the shunt voltage, the gate voltage is set to the power supply voltage by the error amplifier.

5. The shunt circuit according to claim 2, wherein
the first current is on order of nanoampere, and
the second current is on order of microampere.

6. The shunt circuit according to claim 2, wherein the bias circuit sets the operating current to a third current higher than the second current in a predetermined period length from a time when the power supply voltage rises from the second voltage range to the first voltage range, and sets the operating current to the second current after elapse of the period length.

7. The shunt circuit according to an
wherein
the gate voltage in the first bias state is higher than the reference voltage and lower than a threshold voltage of the shunt transistor, and
the gate voltage in the second bias state is higher than the threshold voltage and lower than the shunt voltage.

8. The shunt circuit according to claim 4, wherein
the first current is on order of nanoampere, and
the second current is on order of microampere.

9. The shunt circuit according to claim 4, wherein the bias circuit sets the operating current to a third current higher than the second current in a predetermined period length from a time when the power supply voltage rises from the second voltage range to the first voltage range, and sets the operating current to the second current after elapse of the period length.

10. The shunt circuit according to claim 2, wherein
the gate voltage in the first bias state is higher than the reference voltage and lower than a threshold voltage of the shunt transistor, and
the gate voltage in the second bias state is higher than the threshold voltage and lower than the shunt voltage.

11. The shunt circuit according to claim 3, wherein
the gate voltage in the first bias state is higher than the reference voltage and lower than a threshold voltage of the shunt transistor, and
the gate voltage in the second bias state is higher than the threshold voltage and lower than the shunt voltage.

12. The shunt circuit according to claim 4, wherein
the gate voltage in the first bias state is higher than the reference voltage and lower than a threshold voltage of the shunt transistor, and
the gate voltage in the second bias state is higher than the threshold voltage and lower than the shunt voltage.
